(19) United States
(12) Patent Application Publication
(10) Pub. No.: US 2024/0379168 A1
(43) Pub. Date: Nov. 14, 2024

(54) MEMORY DEVICE

(71) Applicant: SK hynix Inc., Icheon-si Gyeonggi-do (KR)

(72) Inventors: Hyung Jin CHOI, Icheon-si Gyeonggi-do (KR); Gwi Han KO, Icheon-si Gyeonggi-do (KR)

(73) Assignee: SK hynix Inc., Icheon-si Gyeonggi-do (KR)

(21) Appl. No.: 18/461,192

(22) Filed: Sep. 5, 2023

(30) Foreign Application Priority Data
May 11, 2023 (KR) 10-2023-0061142

(51) Int. Cl. G11C 16/16; G11C 16/04; G11C 16/34

(52) U.S. Cl. CPC G11C 16/16; G11C 16/0433; G11C 16/3445

(57) ABSTRACT

A memory device includes strings and a peripheral circuit. The strings are connected between a bit line and a source line. The peripheral circuit is configured to perform an erase operation on a first string among the strings by applying an erase voltage to at least one of the bit line and the source line and configured to control a second string among the strings to be prohibited from being erased during the erase operation.

### CROSS-REFERENCE TO RELATED APPLICATION

The present application claims priority under 35 U.S.C. § 119 (a) to Korean application number 10-2023-0061142, filed on May 11, 2023, in the Korean Intellectual Property Office, which is incorporated herein by reference in its entirety as set forth in full.

### BACKGROUND

### 1. Technical Field

Various embodiments relate to a memory device.

### 2. Related Art

A volatile memory device is a memory device in which the data stored is lost when power supply is interrupted. A non-volatile memory device is a memory device in which the data stored is maintained even when power supply is interrupted. The non-volatile memory device can perform an erase operation to delete the stored data.

### SUMMARY

In an embodiment, a memory device may include strings and a peripheral circuit. The strings may be connected between a bit line and a source line. The peripheral circuit may be configured to perform an erase operation on a first string among the strings by applying an erase voltage to at least one of the bit line and the source line and configured to control a second string among the strings to be prohibited from being erased during the erase operation.

In an embodiment, a memory device may include strings and a peripheral circuit. The strings may be connected between a bit line and a source line. The peripheral circuit may be configured to apply, during a first section in which the peripheral circuit applies a first erase voltage to at least one of the bit line and the source line, an erase select voltage to select lines connected to a first string among the strings while floating select lines connected to a second string among the strings and configured to float, during a second section in which the peripheral circuit applies a second erase voltage to at least one of the bit line and the source line, the select lines connected to the first string and the second string.

In an embodiment, a memory device may include strings and a peripheral circuit. The strings may be connected between a bit line and a source line. The peripheral circuit may be configured to float, while applying an erase voltage to at least one of the bit line and the source line, select lines connected to non-target string among the strings to prohibit memory cells of the non-target string from being erased.

### BRIEF DESCRIPTION OF THE DRAWINGS

FIG. 1 is a block diagram of a memory device according to an embodiment.

FIG. 2 is a circuit diagram illustrating a memory block according to an embodiment.

FIGS. 3 and 4 are circuit diagrams illustrating strings connected to a bit line according to an embodiment.

FIG. 5 is a diagram illustrating an operation of prohibiting one or more non-target strings from being erased during an erase operation on one or more target strings among strings according to an embodiment.

FIG. 6 is a flowchart illustrating an erase operation of a memory device according to an embodiment.

FIG. 7 is a flowchart illustrating an erase operation of a memory device according to an embodiment.

### DETAILED DESCRIPTION

Hereinafter, embodiments of the present disclosure will be described below with reference to the accompanying drawings. In the description of the present disclosure, the terms “first” and “second” may be used to describe various components, but the components are not limited by the terms. The terms may be used to distinguish one component from another component. For example, a first component may be called a second component and a second component may be called a first component without departing from the scope of the present disclosure.

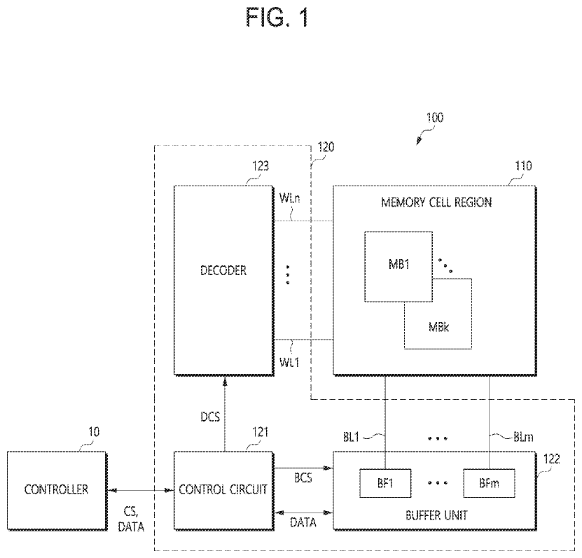

FIG. 1 is a block diagram of a memory device 100 according to an embodiment.

Referring to FIG. 1, the memory device 100 may operate under the control of an external device such as a controller 10. For example, the memory device 100 may perform a program operation, a read operation, an erase operation and so forth under the control of the controller 10. The memory device 100 may communicate with the controller 10 through signals CS and data DATA.

The memory device 100 may be implemented by various types of memory device such as a NAND flash memory, a 3-dimensional (3D) NAND flash memory, a NOR flash memory, a resistive random-access memory (RRAM), a phase change RAM (PRAM), a Magneto-resistive RAM (MRAM), a ferroelectric RAM (FRAM), a spin transfer torque RAM (STT-RAM) and so forth.

The memory device 100 may include a memory cell region 110 and a peripheral circuit 120.

The memory cell region 110 may include a plurality of memory blocks MB1 to MBk. A memory block may serve as a unit for an erase operation performed by the memory device 100. In other words, all data stored in a memory block may be erased simultaneously. The words “simultaneous” and “simultaneously” as used herein with respect to processes mean that the processes take place on overlapping intervals of time. For example, if a first process takes place over a first interval of time and a second process takes place simultaneously over a second interval of time, then the first and second intervals at least partially overlap each other such that there exists a time at which the first and second processes are both taking place. Each of the memory blocks MB1 to MBk may contain multiple memory cells where data is stored. Each of the memory blocks MB1 to MBk may be connected to the peripheral circuit 120 through word lines WL1 to WLn and bit lines BL1 to BLm. The memory cells within each of the memory blocks MB1 to MBk may be arranged in a two-dimensional structure parallel to the substrate or in a three-dimensional structure stacked vertically from the substrate.

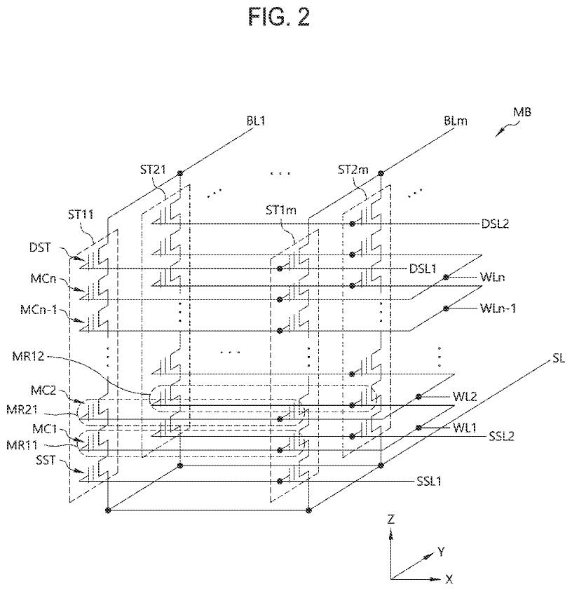

FIG. 2 is a circuit diagram illustrating a memory block MB according to an embodiment. Each of the memory blocks MB1 to MBk of FIG. 1 may be configured in the similar manner to the memory block MB of FIG. 2.

Referring to FIG. 2, the memory block MB may include strings ST11 to ST1m and ST21 to ST2m. Each of the strings ST11 to ST1m and ST21 to ST2m may extend in a vertical direction (e.g., Z-axis). Within the memory block MB, a ‘m’ number of strings may be arranged in a row direction (e.g., X-axis). Although FIG. 2 illustrates two strings being arranged in a column direction (e.g., Y-axis), it is for the convenience of explanation and should be understood that three or more strings may be arranged in the column direction.

The strings ST11 to ST1m and ST21 to ST2m may be configured in the same manner. For example, the string ST11 may include a source select transistor SST, memory cells MC1 to MCn and a drain select transistor DST, which are connected in series between a source line SL and a bit line BL1. The source of the source select transistor SST may be connected to the source line SL and the drain of the drain select transistor DST may be connected to the bit line BL1. The memory cells MC1 to MCn may be connected in series between the source select transistor SST and the drain select transistor DST. In accordance with an embodiment, a plurality of source select transistors may be connected in series between the source line SL and the memory cell MC1. In accordance with an embodiment, the plurality of drain select transistors may be connected in series between the bit line BL1 and the memory cell MCn.

In the vertical direction, the source select transistors arranged at the same location may be configured as follows. Specifically, the gates of the source select transistors of the strings arranged in the same row may be connected to the same source select line. For example, the gates of the source select transistors of the strings ST11 to ST1m arranged in the first row may be connected to the source select line SSL1. For example, the gates of the source select transistors of the strings ST21 to ST2m arranged in the second row may be connected to the source select line SSL2.

In an embodiment, the source select transistors of strings arranged in multiple rows may be commonly connected to a single source select line. For example, the source select transistors of the strings ST11 to ST1m and ST21 to ST2m arranged in the first and second rows may be commonly connected to a single source select line. Similarly, the source select transistors of the strings arranged in the third and fourth rows may be commonly connected to a single source select line.

In the vertical direction, the drain select transistors arranged in the same location may be configured as follows. Specifically, the gates of the drain select transistors of the strings arranged in the same row may be connected to the same drain select 2.5 line. For example, the gates of the drain select transistors of the strings ST11 to ST1m arranged in the first row may be connected to the drain select line DSL1. For example, the gates of the drain select transistors of the strings ST21 to ST2m arranged in the second row may be connected to the drain select line DSL2.

Strings arranged in the same column may be connected to the same bit line. For example, the strings ST11 and ST21 arranged in the first column may be connected to the bit line BL1. For example, the strings ST1m and ST2m arranged in the m-th column may be connected to the bit line BLm.

In the vertical direction, gates of memory cells arranged at the same location may be connected to the same word line. For example, the memory cell MC1 and other memory cells arranged at the same location in the vertical direction in the strings ST11 to ST1m and ST21 to ST2m may be connected to the word line WL1.

Among the memory cells, those connected to the same word line in the same row may form a single memory region. For example, the memory cells connected to the word line WL1 in the first row may form a single memory region MR11. For example, the memory cells connected to the word line WL1 in the second row may form a single memory region MR12. For example, the memory cells connected to the word line WL2 in the first row may form a single memory region MR21. Depending on the number of rows, each word line may be connected to a plurality of memory regions. The memory cells configuring a single memory region may be accessed simultaneously.

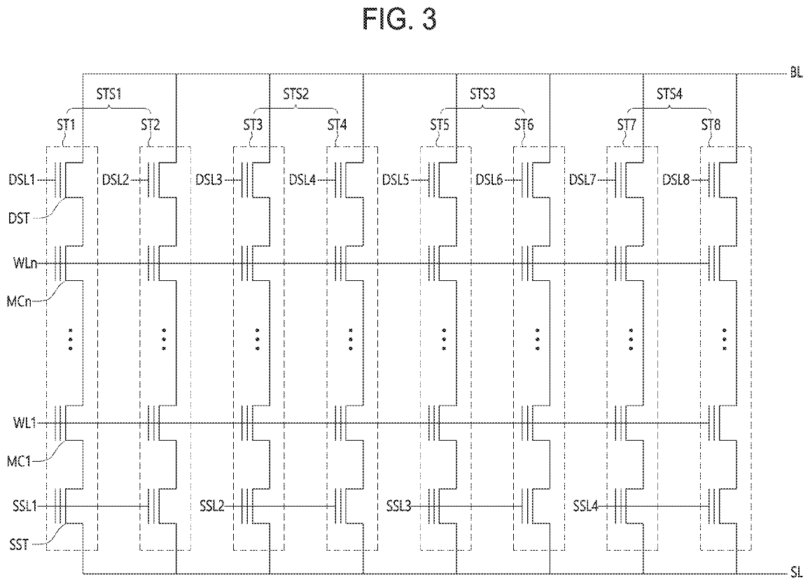

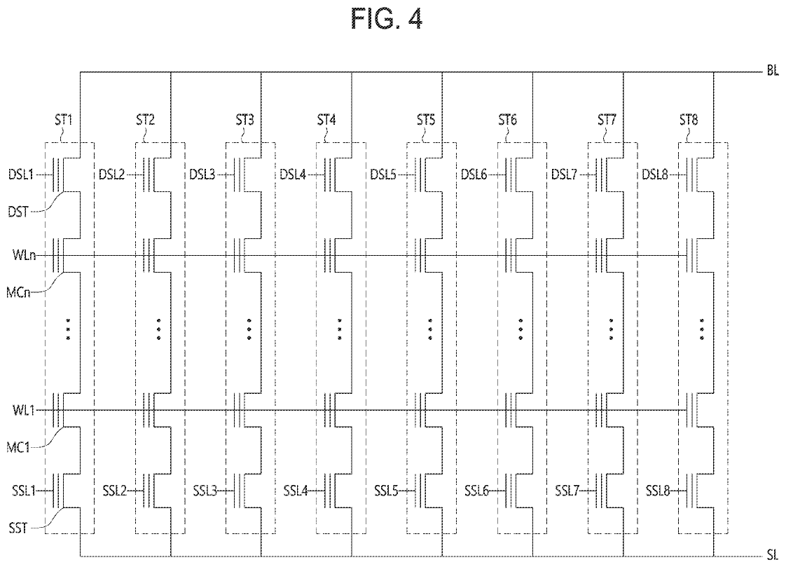

FIGS. 3 and 4 are circuit diagrams illustrating strings ST1 to ST8 connected to a bit line BL according to an embodiment. The bit line BL may correspond to each of the bit lines BL1 to BLm of FIG. 2. Any number of elements illustrated in FIGS. 3 and 4 is an example.

Referring to FIG. 3, the bit line BL may be connected to the strings ST1 to ST8. Each of the strings ST1 to ST8 may be configured in the similar manner to the string ST11 of FIG. 2.

The strings ST1 to ST8 may be grouped into string sets STS1 to STS4. The string sets STS1 to STS4 may be respectively connected to different source select lines SSL1 to SSL4. Each of the string sets STS1 to STS4 may include two strings. The two strings within each of the string sets STS1 to STS4 may be commonly connected to a single source select line. For example, the strings ST1 and ST2 included in the string set STS1 may be commonly connected to the single source select line SSL1.

According to an embodiment, a string set may refer to a collection of one or more strings commonly connected to a single source select line among strings commonly connected to a single bit line within a memory block. As illustrated in FIG. 4, when all the source select transistors of the strings ST1 to ST8 are respectively connected to different source select lines SSL1 to SSL8, each string set may be configured by a single string.

Each of the select transistors (i.e., the source select transistor and the drain select transistor) may be configured and capable of operating in the similar manner to a memory cell. For example, in the string ST1, when a voltage higher than the threshold voltage of the drain select transistor DST is applied to the drain select line DSL1, the drain select transistor DST may be turned on and may connect the string ST1 to the bit line BL. On the other hand, when a voltage lower than the threshold voltage of the drain select transistor DST is applied to the drain select line DSL1, the drain select transistor DST may be turned off and might not connect the string ST1 to the bit line BL.

Referring back to FIG. 1, the peripheral circuit 120 may perform various operations such as a program operation, a read operation and an erase operation on the memory cell region 110 under the control of the controller 10. The peripheral circuit 120 may receive external signals from the controller 10, the external signals including a command, an address and data, and the peripheral circuit 120 may respond to these external signals to perform an operation.

Regarding the erase operation on the memory block MB, the peripheral circuit 120 may control, as described below, the strings (e.g., the strings ST1 to ST8) connected to a single bit line BL. By applying the following scheme to each of the bit lines BL1 to BLm connected to the memory block MB, the peripheral circuit 120 may collectively control all the strings within the memory block MB. Specifically, the peripheral circuit 120 may simultaneously perform the erase operation on the strings ST1 to ST8, perform the erase verify operation on each string set and determine, based on the result of the erase verify operation, a first string (hereinafter, referred to as a target string) and a second string (hereinafter, referred to as a non-target string). More specifically, the peripheral circuit 120 may determine, as the target string, a string in a string set, on which a result of the erase verify operation is erase-fail and may determine, as the non-target string, a string in a string set, on which a result of the erase verify operation is erase-pass. For example, when the result of the erase verify operation on the string set STS2 in FIG. 3 is erase-fail and the result of each erase verify operation on the remaining string sets STS1, STS3 and STS4 is erase-pass, the peripheral circuit 120 may determine the strings ST3 and ST4 as the target strings and may determine the strings ST1, ST2, and ST5 to ST8 as the non-target strings.

In accordance with an embodiment, the peripheral circuit 120 may determine, as the target strings, some of the strings within the string set, on which a result of an erase verify operation is the erase-fail. Additionally, the peripheral circuit 120 may determine, as the non-target strings, a string other than the target string within the string set, on which a result of an erase verify operation is the erase-fail and a string within the string set, on which a result of an erase verify operation is the erase-pass. For example, when the result of the erase verify operation on the string set STS2 of FIG. 3 is the erase-fail and each result of the erase verify operations on the remaining string sets STS1, STS3 and STS4 is the erase-pass, the peripheral circuit 120 may determine the string ST3 as the target string and may determine the strings ST1, ST2 and ST4 to ST8 as the non-target strings.

The peripheral circuit 120 may perform an erase operation on the target string among the strings ST1 to ST8 by applying an erase voltage to at least one of the bit line BL and the source line SL. During the erase operation on the target string, the peripheral circuit 120 may control the non-target strings among the strings ST1 to ST8 to be prohibited from being erased.

Specifically, the peripheral circuit 120 may apply an erase select voltage to select lines (hereinafter, referred to as target select lines) connected to the target string and may float select lines (hereinafter, referred to as non-target select lines) connected to the non-target strings, in a first section during which the peripheral circuit 120 applies a first erase voltage to at least one of the bit line BL and the source line SL. The erase select voltage may be lower than the first erase voltage. The erase select voltage may be a ground voltage. Subsequently, the peripheral circuit 120 may float the target select lines and the non-target select lines in a second section, during which the peripheral circuit 120 applies a second erase voltage to at least one of the bit line BL and the source line SL. The second erase voltage may be higher than the first erase voltage. Additionally, during the first section and the second section, the peripheral circuit 120 may apply the erase select voltage to the word lines connected to the strings ST1 to ST8. Following that, in a third section, the peripheral circuit 120 may interrupt the application of the second erase voltage and may discharge the select lines connected to the bit line BL, the source line SL and the strings ST1 to ST8.

In accordance with an embodiment, the peripheral circuit 120 may perform an erase operation on the target string and then perform an erase verify operation on the target string. Based on the result of the erase verify operation, the peripheral circuit 120 may perform an additional erase operation on the target string in a similar manner as described earlier. In other words, when the result of the erase verify operation on the target string is still the erase-fail, the peripheral circuit 120 may perform an additional erase operation on the target string while controlling the non-target strings, on which a result of an erase verify operation is the erase-pass, to be prohibited from being erased.

Therefore, according to an embodiment, after the erase operation performed simultaneously on the strings ST1 to ST8, the erase operation may be performed only on one or more strings (i.e., the target strings) that have not been completely erased. As a result, according to an embodiment, erase voltage is prohibited from being unnecessarily applied to the memory cells of completely erased strings (i.e., the non-target strings). Furthermore, according to an embodiment, the threshold voltages of the memory cells in the completely erased strings (i.e., the non-target strings) may be prohibited from becoming excessively lowered due to unnecessary erase operations.

The peripheral circuit 120 may include a control circuit 121, a buffer unit 122 and a decoder 123. Each of the control circuit 121, the buffer unit 122 and the decoder 123 may be embodied by hardware, software, firmware or a combination thereof.

The control circuit 121 may exchange the signals CS and the data DATA with the controller 10. The control circuit 121 may control overall operations of the memory device 100 based on external signals provided from controller 10. Specifically, the control circuit 121 may generate buffer control signals BCS to output the buffer control signals BCS to buffer unit 122. The control circuit 121 may generate decoder control signals DCS and output the decoder control signals DCS to decoder 123. For instance, the decoder control signals DCS may include operation voltages of various levels such as a program voltage, a read voltage, an erase voltage, a verify voltage and so fourth. The operation voltages may be required for a program operation, a read operation and an erase operation. Although not illustrated, the control circuit 121 may include an interface for communication with the controller 10 and a voltage generation circuit configured to generate the various levels of operation voltages.

The buffer unit 122 may be connected to the memory cell region 110 through the bit lines BL1 to BLm. The buffer unit 122 may be connected to each of the memory blocks MB1 to MBk through the bit lines BL1 to BLm. The buffer unit 122 may include a plurality of bit line control circuits BF1 to BFm connected to the respective bit lines BL1 to BLm. The bit line control circuits BF1 to BFm may be connected to memory cells through the respective bit lines BL1 to BLm. The bit line control circuits BF1 to BFm may store therein data to be stored in the memory cells. The bit line control circuits BF1 to BFm may temporarily store therein data read from the memory cells. The bit line control circuits BF1 to BFm may exchange data DATA with the control circuit 121. Each of the bit line control circuits BF1 to BFm may sense voltage or current, which is formed as the memory cell responds to a particular voltage to become turned on or off. Each of the bit line control circuits BF1 to BFm may determine, based on the result of the sensing, a value corresponding to the state (e.g., the programmed state and the erased state) of the memory cell. The bit line control circuits BF1 to BFm may operate simultaneously in response to the buffer control signals BCS to simultaneously access the memory cells connected to the respective bit lines BL1 to BLm.

The decoder 123 may be connected to the memory cell region 110 through the word lines WL1 to WLn. The decoder 123 may be connected to each of the memory blocks MB1 to MBk through the word lines WL1 to WLn. Under the control of control circuit 121, the decoder 123 may select, among the word lines WL1 to WLn, one or more word lines connected to memory cells, on which a program operation, a read operation or an erase operation is to be performed. The decoder 123 may then apply the various levels of operation voltage to the selected word lines.

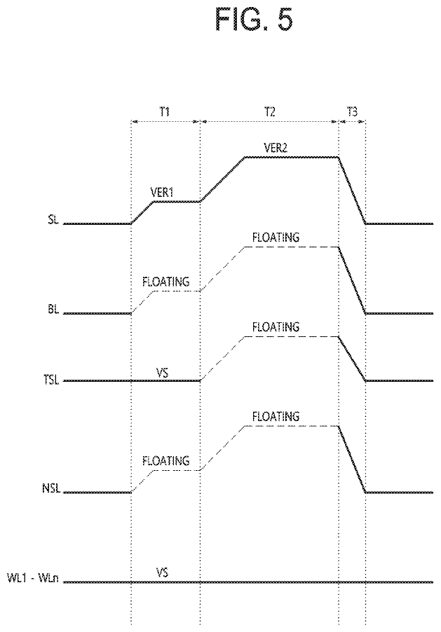

FIG. 5 is a diagram illustrating an operation of prohibiting one or more non-target strings from being erased during an erase operation on one or more target strings among the strings ST1 to ST8 in accordance with an embodiment.

Referring to FIG. 5, the operation during a first section T1 may be described as follows. First, the first erase voltage VER1 may be applied to the source line SL. The control circuit 121 may generate the first erase voltage VER1 and may apply the first erase voltage VER1 to the source line SL. The voltage of the bit line BL may rise due to the coupling effect caused by the first erase voltage VER1 applied to the source line SL. According to an embodiment, the first erase voltage VER1 may be directly applied to the bit line BL. According to an embodiment, the first erase voltage VER1 may be applied to the bit line BL and the voltage of the source line SL may rise due to the coupling effect caused by the first erase voltage VER1 applied to the bit line BL.

During the first section T1, the erase select voltage VS (e.g., a ground voltage) may be applied to the target select lines TSL connected to one or more target strings. The erase select voltage VS may be lower than the first erase voltage VER1. The control circuit 121 may generate the erase select voltage VS and may apply the erase select voltage VS to the target select lines TSL. The target select lines TSL may include one or more drain select lines and one or more source select lines, which are connected to one or more target strings. In response to the erase select voltage VS applied to the target select lines TSL, the select transistors (hereinafter, referred to as target select transistors) included in in the target strings may be turned off. As the voltages of the source line SL and the bit line BL increase, the gate induced drain leakage (GIDL) may be induced in the target select transistors. Additionally, due to the GIDL, hot holes may flow into the channels of the target strings.

During the first section T1, the non-target select lines NSL connected to one or more non-target strings may be floated. The control circuit 121 may control the non-target select lines NSL to be floated. The non-target select lines NSL may include one or more drain select lines and one or more source select lines, which are connected to one or more non-target strings. By floating the non-target select lines NSL, there might not be any potential difference between the source lines SL and the bit line BL of the non-target select lines NSL. As a result, the GIDL might not be induced in the non-target strings and there might not be any hot hole caused by the GIDL.

During the first section T1, the erase select voltage VS may be applied to the word lines WL1 to WLn connected to the strings ST1 to ST8. The control circuit 121 may apply the erase select voltage VS to the word lines WL1 to WLn.

The operation during a second section T2 subsequent to the first section T1 may be described as follows. During the second section T2, the second erase voltage VER2 may be applied to the source line SL. The second erase voltage VER2 may be higher than the first erase voltage VER1. The control circuit 121 may generate the second erase voltage VER2 and apply the second erase voltage VER2 to the source line SL. The voltage of the bit line BL may rise due to the coupling effect caused by the second erase voltage VER2 applied to the source line SL. According to an embodiment, the second erase voltage VER2 may be directly applied to the bit line BL. According to an embodiment, the second erase voltage VER2 may be applied to the bit line BL and the voltage of the source line SL may rise due to the coupling effect caused by the second erase voltage VER2 applied to the bit line BL.

During the second section T2, the non-target select lines NSL may continue being floated ever since the first section T1. In other words, the non-target select lines NSL may stay floated during the entire section where the erase voltage is applied, the entire section including the first section T1 and the second section T2. During the second section T2, the target select lines TSL may also be floated. Accordingly, the voltages of all select lines (i.e., both the target select lines TSL and the non-target select lines NSL) connected to the strings ST1 to ST8 may rise due to the coupling effect caused by the second erase voltage VER2 applied to the source line SL.

During the second section T2, as the voltages of the source line SL and the bit line BL rise, the voltages of the channels in the target strings may rise due to the influx of the hot holes into the target strings. As a result, the memory cells included in the target strings may be erased through the FN tunnelling. However, because the voltages of the channels in the non-target strings do not rise and the hot holes are not generated, the memory cells included in the non-target strings might not be erased.

During a third section T3 subsequent to the second section T2, the bit line BL, the source line SL, the target select lines TSL and the non-target select lines NSL may be discharged. The control circuit 121 may stop the application of the second erase voltage VER2 to the source line SL and may control the discharge of the bit line BL, the source line SL, the target select lines TSL and the non-target select lines NSL.

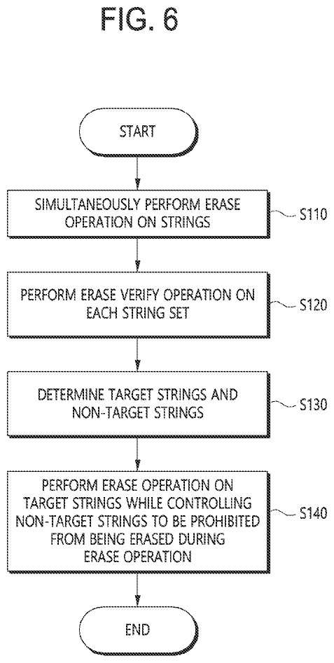

FIG. 6 is a flowchart illustrating an erase operation of the memory device 100 according to an embodiment.

Referring to FIG. 6, in step S110, the peripheral circuit 120 may perform an erase operation on the strings ST1 to ST8 simultaneously. For example, the peripheral circuit 120 may perform the erase operation by controlling all the strings ST1 to ST8 as the target strings in the similar manner to what is described above.

In step S120, the peripheral circuit 120 may perform an erase verify operation on each of the string sets. For example, the peripheral circuit 120 may perform the erase operation by applying an erase verify voltage to the memory cells included in each of the string sets and by identifying threshold voltages of the memory cells.

In step S130, the peripheral circuit 120 may determine one or more target strings and one or more non-target strings among the strings ST1 to ST8. The peripheral circuit 120 may determine, as the target strings, strings within the string set, on which a result of the erase verify operation is the erase-fail. The peripheral circuit 120 may determine, as the non-target strings, strings within the string set, on which a result of the erase verify operation is the erase-pass. The peripheral circuit 120 may determine the result of the erase verify operation as the erase-fail on a string set when the number of memory cells having the threshold voltages higher than the erase verify voltage is equal to or greater than a reference number within the string set. The peripheral circuit 120 may determine the result of the erase verify operation as the erase-pass on a string set when the number of memory cells having the threshold voltages higher than the erase verify voltage is less than the reference number within the string set.

In step S140, the peripheral circuit 120 may perform an erase operation on one or more target strings while controlling one or more non-target strings to be prohibited from being erased during the erase operation on the target strings. While applying the erase voltage to at least one of the bit line BL and the source line SL and applying the erase select voltage VS to the word lines WL1 to WLn, the peripheral circuit 120 may differently control the target select lines TSL of the target strings and the non-target select lines NSL of the non-target strings thereby controlling the non-target strings to be prohibited from being erased.

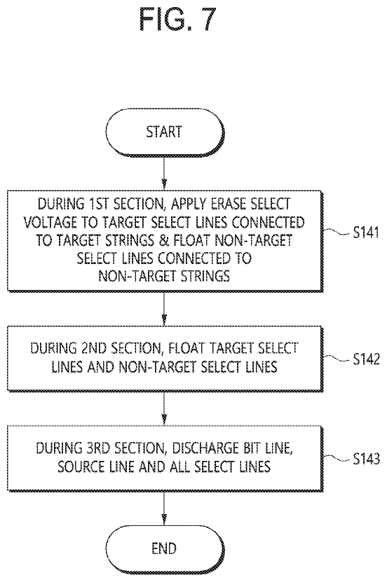

FIG. 7 is a flowchart illustrating an erase operation of the memory device 100 according to an embodiment. The process illustrated in FIG. 7 may be an embodiment of step S140 of FIG. 6.

In step S141, the peripheral circuit 120 may apply, during the first section T1, the first erase voltage VER1 to at least one of the bit line BL and the source line SL. During the first section T1, the peripheral circuit 120 may apply the erase select voltage VS to the target select lines TSL connected to the target strings and may float the non-target select lines NSL connected to the non-target strings.

In step S142, the peripheral circuit 120 may apply, during the second section T2, the second erase voltage VER2 to at least one of the bit line BL and the source line SL. The peripheral circuit 120 may float, during the second section T2, the target select lines TSL and the non-target select lines NSL.

In step S143, during the third section T3, the peripheral circuit 120 may stop applying the second erase voltage VER2 and may discharge the bit line BL, source line SL and all select lines connected to the strings ST1 to ST8.

While certain embodiments have been described above, it will be understood to those skilled in the art that the embodiments described are by way of example only. Accordingly, the memory device should not be limited based on the described embodiments. Rather, the memory device described herein should only be limited in light of the claims that follow when taken in conjunction with the above description and accompanying drawings.

What is claimed is:

1. A memory device comprising:
strings connected between a bit line and a source line; and
a peripheral circuit configured to perform an erase operation on a first string among the strings by applying an erase voltage to at least one of the bit line and the source line and configured to control a second string among the strings to be prohibited from being erased during the erase operation.

2. The memory device of claim 1, wherein the peripheral circuit is configured to float select lines connected to the second string during an entire duration, in which the peripheral circuit applies the erase voltage.

3. The memory device of claim 1, wherein the peripheral circuit is configured to apply, during a first section in which the peripheral circuit applies a first erase voltage as the erase voltage, an erase select voltage lower than the first erase voltage to select lines connected to the first string and configured to float the select lines during a second section in which the peripheral circuit applies a second erase voltage as the erase voltage, the second section being subsequent to the first section.

4. The memory device of claim 3, wherein the peripheral circuit is configured to stop, during a third section subsequent to the second section, the applying of the second erase voltage while discharging the bit line, the source line and select lines connected to the strings.

5. The memory device of claim 1, wherein the peripheral circuit is configured to apply an erase select voltage lower than the erase voltage to word lines connected to the strings during an entire duration, in which the peripheral circuit applies the erase voltage.

6. The memory device of claim 1, wherein the peripheral circuit is configured to simultaneously perform an erase operation on the strings, configured to perform an erase verify operation on each of string sets and configured to determine the first string and the second string based on a result of the erase verify operation.

7. The memory device of claim 6, wherein the peripheral circuit is configured to determine, as the first string, a string in a string set, on which the result of the erase verify operation is erase-fail and configured to determine, as the second string, a string in a string set, on which the result of the erase verify operation is erase-pass.

8. The memory device of claim 1,
wherein each of the strings includes one or more drain select transistors, one or more source select transistors, and memory cells connected between the drain select transistors and the source select transistors,
wherein the drain select transistors, the memory cells, and the source select transistors are connected in series between the bit line and the source line, and
wherein each of the drain select transistors and the source select transistors is configured to be turned on in response to corresponding select line.

9. A memory device comprising:
strings connected between a bit line and a source line; and
a peripheral circuit configured to apply, during a first section in which the peripheral circuit applies a first erase voltage to at least one of the bit line and the source line, an erase select voltage to select lines connected to a first string among the strings while floating select lines connected to a second string among the strings and configured to float, during a second section in which the peripheral circuit applies a second erase voltage to at least one of the bit line and the source line, the select lines connected to the first string and the second string.

10. The memory device of claim 9, wherein the peripheral circuit is configured to apply the erase select voltage to word lines connected to the strings during the first section and the second section.

11. The memory device of claim 9, wherein the peripheral circuit is configured to stop, during a third section subsequent to the second section, the applying of the second erase voltage while discharging the bit line, the source line and the select lines connected to the strings.

12. The memory device of claim 9,
wherein the erase select voltage is lower than the first erase voltage, and
wherein the second erase voltage is higher than the first erase voltage.

13. The memory device of claim 9, wherein the peripheral circuit is configured to simultaneously perform an erase operation on the strings, configured to perform an erase verify operation on each of string sets and configured to determine the first string and the second string based on a result of the erase verify operation.

14. The memory device of claim 13, wherein the peripheral circuit is configured to determine, as the first string, a string in a string set, on which the result of the erase verify operation is erase-fail and configured to determine, as the second string, a string in a string set, on which the result of the erase verify operation is erase-pass.

15. A memory device comprising:
strings connected between a bit line and a source line; and
a peripheral circuit configured to float, while applying an erase voltage to at least one of the bit line and the source line, select lines connected to non-target string among the strings to prohibit memory cells of the non-target string from being erased.

16. The memory device of claim 15, wherein the peripheral circuit is configured to apply, during a first section in which the peripheral circuit applies a first erase voltage as the erase voltage, an erase select voltage lower than the first erase voltage to select lines connected to a target string among the strings and configured to float, during a second section in which the peripheral circuit applies a second erase voltage as the erase voltage, the select lines connected to the target string, the second section being subsequent to the first section.

17. The memory device of claim 16, wherein the peripheral circuit is configured to stop, during a third section subsequent to the second section, the applying of the second erase voltage while discharging the bit line, the source line and select lines connected to the strings.

18. The memory device of claim 15, wherein the peripheral circuit is configured to apply an erase select voltage lower than the erase voltage to word lines connected to the strings during the applying of the erase voltage.

19. The memory device of claim 15, wherein the peripheral circuit is configured to simultaneously perform an erase operation on the strings, configured to perform an erase verify operation on each of string sets and configured to determine the non-target string based on a result of the erase verify operation.

20. The memory device of claim 19, wherein the peripheral circuit is configured to determine, as the non-target string, a string in a string set, on which the result of the erase verify operation is erase-pass.
